(19) United States
(12) Patent Application Publication
(10) Pub. No.: US 2025/0167162 A1
(43) Pub. Date: May 22, 2025

(54) ELECTRONIC PACKAGE AND SUBSTRATE STRUCTURE THEREOF

(71) Applicant: SILICONWARE PRECISION INDUSTRIES CO., LTD., Taichung City (TW)

(72) Inventors: Wei-Hsin SHIH, Taichung City (TW); Chin-Wei HSU, Taichung City (TW); Jui-Kun WANG, Taichung City (TW); Yi-Han LU, Taichung City (TW); Hsiu-Fang CHIEN, Taichung City (TW)

(21) Appl. No.: 18/949,476

(22) Filed: Nov. 15, 2024

(30) Foreign Application Priority Data
Nov. 16, 2023 (TW) 112144348

(51) Int. Cl. H01L 23/00; H01L 23/498

(52) U.S. Cl. CPC H01L 24/32; H01L 23/49811; H01L 24/16; H01L 24/73; H01L 2224/16237; H01L 2224/26175; H01L 2224/32225; H01L 2224/73204

(57) ABSTRACT

An electronic package and a substrate structure thereof are provided, in which an electronic element is disposed on the substrate structure having a circuit layer, and an insulating protective layer of the substrate structure has an opening that exposes the circuit layer. A plurality of extension portions protruding toward the inside of the opening and spaced apart are formed on the edge of the opening of the insulating protective layer, so that when an underfill material is filled into a space between the electronic element and the substrate structure, the space between the electronic element and the substrate structure can be evenly filled up to prevent the underfill material from forming voids.

### CROSS-REFERENCE TO RELATED APPLICATIONS

The present application is based upon and claims the right of priority to TW Patent Application No. 112144348, filed Nov. 16, 2023, the disclosure of which is hereby incorporated by reference herein in its entirety for all purposes.

### BACKGROUND

### 1. Technical Field

The present disclosure relates to a semiconductor packaging technology, and more particularly, to an electronic package and a substrate structure thereof.

### 2. Description of Related Art

With the development of the electronics industry, today's electronic products have tended to be designed in the direction of being light, thin, compact and with diversified functions. Semiconductor packaging technology has also developed different packaging types. In order to meet the high integration and miniaturization needs of semiconductor devices, in addition to the traditional wire bonding semiconductor packaging technology, the flip-chip method can also be used to improve wiring density.

FIG. 1 is a schematic cross-sectional view of a conventional flip-chip semiconductor package 1. As shown in FIG. 1, an insulating protective layer 12 of a package substrate 10 is formed with a plurality of openings 120 corresponding to and exposing a circuit layer 100, so that a semiconductor chip 11 is bonded to the circuit layer 100 through the openings 120 via a plurality of solder bumps 13 to be electrically connected to the circuit layer 100. An underfill 14 is then formed between the semiconductor chip 11 and the package substrate 10 to cover the solder bumps 13.

However, when the underfill 14 flows between the semiconductor chip 11 and the package substrate 10, the underfill 14 is often unable to fill up the tiny gaps between the solder bumps 13. Therefore, voids P are easily formed between the solder bumps 13, causing popcorn phenomenon to easily occur in subsequent processes, thereby resulting in a reduction in product yield.

Therefore, how to overcome the above problems of the prior art has become an urgent problem to be solved.

### SUMMARY

In view of the various deficiencies of the prior art, the present disclosure provides a substrate structure, which comprises: a substrate body having a circuit layer and defined with at least one die placement region; and an insulating protective layer formed on the substrate body and formed with an opening corresponding to the die placement region and exposing the circuit layer, wherein the insulating protective layer is formed with a plurality of spaced extension portions protruding toward an inside of the opening at an edge of the opening.

The present disclosure also provides an electronic package, which comprises: the aforementioned substrate structure; an electronic element disposed on the die placement region and electrically connected to the circuit layer; and an underfill material formed between the substrate structure and the electronic element and filling up the opening.

In the aforementioned electronic package and substrate structure, a length of each of the extension portions is 1200 microns to 1800 microns, and a distance between the extension portions is 70 microns to 130 microns. In addition, the circuit layer has a plurality of conductive traces and a plurality of electrical contact pads connected to the plurality of conductive traces, and the plurality of electrical contact pads are exposed from the single opening. For example, the electronic element is bonded and electrically connected to the plurality of electrical contact pads via a plurality of conductive bumps.

In the aforementioned electronic package and substrate structure, a plurality of guide blocks arranged and spaced apart are formed in the opening to form a plurality of channels. For example, an opening direction of the channel is the same as a molding flow direction of the underfill material.

In the aforementioned electronic package and substrate structure, the insulating protective layer is formed with at least one recess on a periphery of the die placement region. For example, the recess communicates with the opening.

In the aforementioned electronic package and substrate structure, the electronic element is bonded and electrically connected to the circuit layer via a plurality of conductive bumps. For example, the underfill material covers the plurality of conductive bumps.

To sum up, in the electronic package and the substrate structure thereof of the present disclosure, the extension portion of the insulating protective layer is designed to be intermittent (discontinuous), and its length and spacing distance are limited at the same time, so that when the underfill material quickly flows into the opening, the flow efficiency of the molding colloid of the underfill material can be increased so that the underfill material can be evenly spread in the space between the electronic element and the substrate structure. At the same time, the use of the guide blocks allows the molding colloid of the underfill material to diffuse by capillary action and flow along the guide blocks, thereby preventing the underfill material from forming voids, thus improving product yield.

### BRIEF DESCRIPTION OF THE DRAWINGS

FIG. 1 is a schematic cross-sectional view of a conventional semiconductor package.

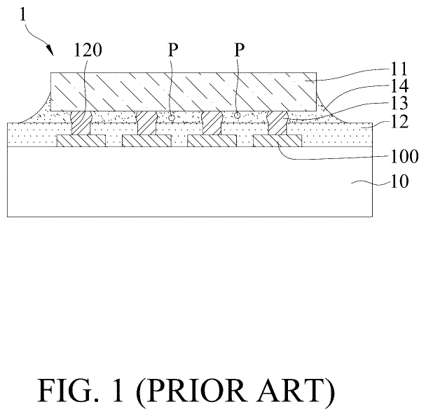

FIG. 2A is a schematic cross-sectional view of an electronic package according to a first embodiment of the present disclosure.

FIG. 2B is a partial top view of a substrate structure according to the first embodiment of the present disclosure.

FIG. 3A is a schematic cross-sectional view of the electronic package according to a second embodiment of the present disclosure.

FIG. 3B is a partial top view of the substrate structure according to the second embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

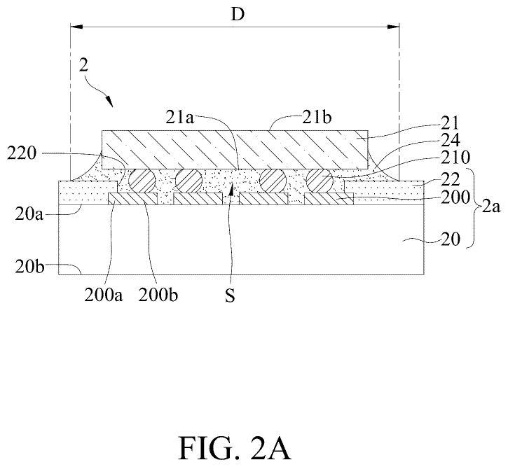

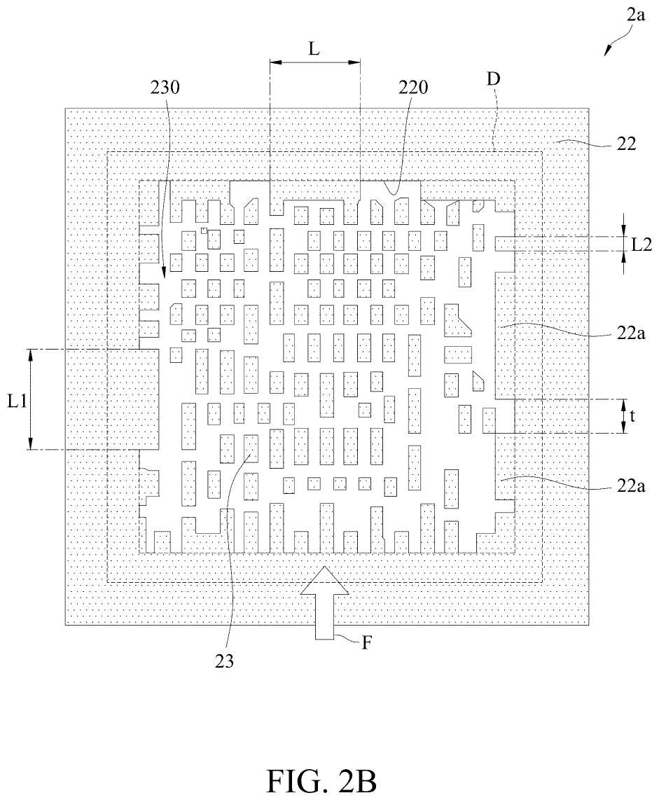

FIG. 2A is a schematic cross-sectional view of an electronic package 2 according to a first embodiment of the present disclosure, FIG. 2B is a schematic top view of a substrate structure 2a according to the first embodiment of the present disclosure, and a circuit layer 200 is omitted in FIG. 2B.

As shown in FIG. 2A, an electronic element 21 is bonded to a substrate structure 2a, and then an underfill material 24 is formed between the electronic element 21 and the substrate structure 2a, wherein the substrate structure 2a includes a substrate body 20 having a circuit layer 200 and an insulating protective layer 22.

The substrate body 20 has a first surface 20a and a second surface 20b opposite to the first surface 20a, and a die placement region D is defined on the first surface 20a, as shown in FIG. 2B.

In one embodiment, the substrate body 20 is a package substrate having a core layer and a circuit structure, a package substrate having a coreless circuit structure, or other board types.

Furthermore, the substrate body 20 is used with a redistribution layer (RDL) manufacturing method to form a package substrate, which has an insulating layer and a circuit layer 200 bonded to the insulating layer. For example, the circuit layer 200 is made of copper, and the insulating layer is made of polybenzoxazole (PBO), polyimide (PI), prepreg (PP), or other dielectric materials.

In addition, the circuit layer 200 on the first surface 20a of the substrate body 20 has a plurality of conductive traces 200a and a plurality of electrical contact pads 200b connected to the conductive traces 200a.

The insulating protective layer 22 is used as a solder-resist layer, such as solder mask, and is formed on the first surface 20a of the substrate body 20, and an opening 220 is formed corresponding to the die placement region D to expose the plurality of electrical contact pads 200b.

In one embodiment, the insulating protective layer 22 is formed with a plurality of extension portions 22a protruding toward the inside of the opening 220 at the edge of the opening 220. According to simulation and actual measurement results, the length L of the extension portion 22a corresponding to the edge of the opening 220 is 1200 microns to 1800 microns (μm), and the distance t between the extension portions 22a is 70 microns to 130 microns. It should be understood that in a single substrate body 20, the lengths L1 and L2 of each extension portion 22a may be the same or different.

Furthermore, a plurality of island-shaped guide blocks 23 arranged and spaced apart are formed in the opening 220 to form a plurality of strip-shaped channels 230 (which can be regular or irregular strips), and the channels 230 are staggered and interconnected. For example, the material forming the guide blocks 23 is the same as or different from the material of the insulating protective layer 22. It should be understood that the channels 230 can also be arranged side by side without being connected to each other.

The electronic element 21 is an active element, a passive element, or a combination of the active element and the passive element, and the electronic element 21 is disposed on the die placement region D, wherein the active element is, for example, a semiconductor chip, and the passive element is, for example, a resistor, a capacitor, or an inductor.

In one embodiment, the electronic element 21 is a semiconductor chip and has an active surface 21a and an inactive surface 21b opposite to the active surface 21a, and the active surface 21a of the electronic element 21 is electrically connected to the circuit layer 200 via a plurality of conductive bumps 210 such as copper pillars, solder materials, or the like, which are disposed on the plurality of electrical contact pads 200b in a flip-chip manner.

The underfill material 24 is formed between the substrate structure 2a and the electronic element 21 and fills up the opening 220 and covers the conductive bumps 210.

In one embodiment, the underfill material 24 is an insulating material, such as underfill, polyimide (PI), dry film, or molding colloid of epoxy.

Furthermore, the outline of the die placement region D is determined according to the shape of the electronic element 21, and the area of the die placement region D is approximately equal to the layout range of the underfill material 24, so that the area of the die placement region D is larger than the area of the electronic element 21.

In addition, when the process of the underfill material 24 is performed, the single opening 220 of the insulating protective layer 22 prevents the insulating protective layer 22 from blocking the electrical contact pads 200b (the electrical contact pads 200b may also be blocked by the insulating protective layer 22, not shown in the figure). Therefore, larger particles in the underfill material 24 can easily pass between the electronic element 21 and the substrate structure 2a, and the channel 230 corresponds to the filling direction of the underfill material 24, that is, a molding flow direction F (as shown in FIG. 2B), so that the underfill material 24 flows into the opening 220 according to the molding flow direction F. Therefore, when larger particles in the underfill material 24 touch the guide blocks 23, they can still bypass the guide blocks 23 and continue to flow along the channel 230 to the other end to avoid the flow of the underfill material 24 from being blocked. At the same time, the guide blocks 23 can be used to cause the molding colloid of the underfill material 24 to diffuse by capillary action and flow along the guide blocks 23.

Therefore, in the electronic package 2 of the present disclosure, the extension portion 22a of the substrate structure 2a has an intermittent (discontinuous) design, while limiting its length and spacing distance. For example, the length L is designed to be 1200 microns to 1800 microns and the distance t between the extension portions 22a is 70 microns to 130 microns, so that when the underfill material 24 flows into the opening 220 quickly, the flow efficiency of the molding colloid of the underfill material 24 can be increased so that the underfill material 24 can be evenly spread in a space S between the electronic element 21 and the substrate structure 2a. Therefore, compared with the prior art, the underfill material 24 of the electronic package 2 of the present disclosure can fill up the space S between the electronic element 21 and the substrate structure 2a (or the gap between the conductive bumps 210), so as to avoid forming voids in the space S between the electronic element 21 and the substrate structure 2a (or between the conductive bumps 210).

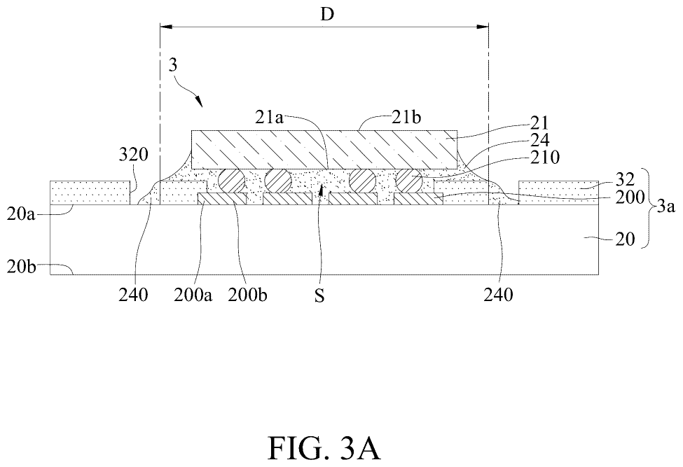

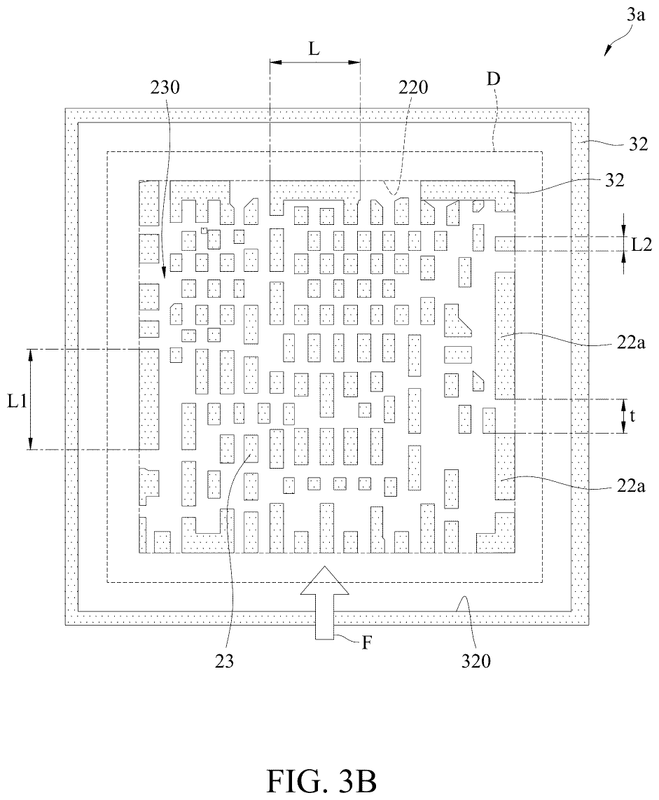

FIG. 3A is a schematic cross-sectional view of an electronic package 3 according to a second embodiment of the present disclosure, FIG. 3B is a schematic top view of a substrate structure 3a according to the second embodiment of the present disclosure, and the circuit layer 200 is omitted in FIG. 3B. The difference between this embodiment and the first embodiment is that a recess 320 is added to the insulating protective layer 32. The other structures are generally the same, so the similarities will not be described again.

As shown in FIG. 3A and FIG. 3B, the insulating protective layer 32 is formed with at least one recess 320 on the periphery of the die placement region D.

In one embodiment, the recess 320 is connected to the opening 220. For example, the recess 320 surrounds the die placement region D to form an annular trench, so that the insulating protective layer 32 forms an inner ring and an outer ring shape. It should be understood that the depth of the recess 320 may be less than or equal to the thickness of the insulating protective layer 32.

Therefore, in the electronic package 3 of the present disclosure, a configuration of the recess 320 is employed so that when the flow rate of the underfill material 24 is too much, an overflow portion 240 of the underfill material 24 can flow into the recess 320 from the channel 230, such that the recess 320 receives the overflow portion 240 of the underfill material 24. Therefore, even if the underfill material 24 overflows, the underfill material 24 will not flow inappropriately to other regions of the insulating protective layer 32 and affect the subsequent semiconductor packaging process, and can even avoid contamination of other regions.

It should be understood that the shape and position of the recess 320 can be designed according to needs and is not limited to the above.

The present disclosure also provides a substrate structure 2a, 3a, which comprises: a substrate body 20 having a circuit layer 200 and an insulating protective layer 22, 32 formed on the substrate body 20.

The substrate body 20 is defined with at least one die placement region D.

The insulating protective layer 22, 32 has an opening 220 exposing the circuit layer 200, wherein the insulating protective layer 22, 32 is formed with a plurality of spaced extension portions 22a protruding toward the inside of the opening 220 at the edge of the opening 220, the length L of the extension portion 22a is 1200 microns to 1800 microns, and the distance t between the extension portions 22a is 70 microns to 130 microns.

In one embodiment, the circuit layer 200 has a plurality of conductive traces 200a and a plurality of electrical contact pads 200b connected to the conductive traces 200a, so that the plurality of electrical contact pads 200b are exposed from the single opening 220.

In one embodiment, a plurality of guide blocks 23 arranged and spaced apart are formed in the opening 220 to form a plurality of channels 230.

In one embodiment, the insulating protective layer 32 is formed with at least one recess 320 on the periphery of the die placement region D. For example, the recess 320 communicates with the opening 220.

The present disclosure also provides an electronic package 2, 3, which comprises: the substrate structure 2a, 3a, at least one electronic element 21 and an underfill material 24.

The electronic element 21 is disposed on the die placement region D and is electrically connected to the circuit layer 200.

The underfill material 24 is formed between the substrate structure 2a, 3a and the electronic element 21 and fills up the opening 220.

In one embodiment, the circuit layer 200 has a plurality of conductive traces 200a and a plurality of electrical contact pads 200b connected to the conductive traces 200a, so that the plurality of electrical contact pads 200b are exposed from the single opening 220. For example, the electronic element 21 is bonded and electrically connected to the plurality of electrical contact pads 200b via a plurality of conductive bumps 210.

In one embodiment, a plurality of guide blocks 23 arranged and spaced apart are formed in the opening 220 to form a plurality of channels 230. For example, the opening direction of the channel 230 is the same as the molding flow direction F of the underfill material 24.

In one embodiment, the insulating protective layer 32 is formed with at least one recess 320 on the periphery of the die placement region D. For example, the recess 320 communicates with the opening 220.

In one embodiment, the electronic element 21 is bonded and electrically connected to the circuit layer 200 via a plurality of conductive bumps 210. For example, the underfill material 24 covers the plurality of conductive bumps 210.

To sum up, in the electronic package and the substrate structure thereof of the present disclosure, the extension portion of the insulating protective layer is designed to be intermittent (discontinuous), and its length and spacing distance are limited at the same time, so that when the underfill material quickly flows into the opening, the flow efficiency of the molding colloid of the underfill material can be increased so that the underfill material can be evenly spread in the space between the electronic element and the substrate structure. At the same time, the use of the guide blocks allows the molding colloid of the underfill material to diffuse by capillary action and flow along the guide blocks, thereby preventing the underfill material from forming voids, thus improving product yield.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A substrate structure, comprising:
a substrate body having a circuit layer and defined with at least one die placement region; and
an insulating protective layer formed on the substrate body and formed with an opening corresponding to the die placement region and exposing the circuit layer, wherein the insulating protective layer is formed with a plurality of spaced extension portions protruding toward an inside of the opening at an edge of the opening.

2. The substrate structure of claim 1, wherein a length of each of the extension portions is 1200 microns to 1800 microns, and a distance between the extension portions is 70 microns to 130 microns.

3. The substrate structure of claim 1, wherein the circuit layer has a plurality of conductive traces and a plurality of electrical contact pads connected to the plurality of conductive traces, and the plurality of electrical contact pads are exposed from the single opening.

4. The substrate structure of claim 1, wherein a plurality of guide blocks arranged and spaced apart are formed in the opening to form a plurality of channels.

5. The substrate structure of claim 1, wherein the insulating protective layer is formed with at least one recess on a periphery of the die placement region.

6. The substrate structure of claim 5, wherein the recess communicates with the opening.

7. An electronic package, comprising:
the substrate structure of claim 1;
an electronic element disposed on the die placement region and electrically connected to the circuit layer; and
an underfill material formed between the substrate structure and the electronic element and filling up the opening.

8. The electronic package of claim 7, wherein a length of each of the extension portions is 1200 microns to 1800 microns, and a distance between the extension portions is 70 microns to 130 microns.

9. The electronic package of claim 7, wherein the circuit layer has a plurality of conductive traces and a plurality of electrical contact pads connected to the plurality of conductive traces, and the plurality of electrical contact pads are exposed from the single opening.

10. The electronic package of claim 9, wherein the electronic element is bonded and electrically connected to the plurality of electrical contact pads via a plurality of conductive bumps.

11. The electronic package of claim 7, wherein a plurality of guide blocks arranged and spaced apart are formed in the opening to form a plurality of channels.

12. The electronic package of claim 11, wherein an opening direction of the channel is the same as a molding flow direction of the underfill material.

13. The electronic package of claim 7, wherein the insulating protective layer is formed with at least one recess on a periphery of the die placement region.

14. The electronic package of claim 13, wherein the recess communicates with the opening.

15. The electronic package of claim 7, wherein the electronic element is bonded and electrically connected to the circuit layer via a plurality of conductive bumps.

16. The electronic package of claim 15, wherein the underfill material covers the plurality of conductive bumps.
